(19) United States
(12) Patent Application Publication
(10) Pub. No.: US 2022/0299173 A1
(43) Pub. Date: Sep. 22, 2022

(54) LIGHT EMITTING DEVICE

(71) Applicant: SHARP KABUSHIKI KAISHA, Sakai City (JP)

(72) Inventors: HIROAKI ONUMA, Sakai City (JP); TOSHIO HATA, Sakai City (JP); YASUAKI HIRANO, Sakai City (JP)

(21) Appl. No.: 17/834,393

(22) Filed: Jun. 7, 2022

Related U.S. Application Data
(62) Division of application No. 16/789,285, filed on Feb. 12, 2020.
(60) Provisional application No. 62/808,556, filed on Feb. 21, 2019.

(51) Int. Cl. F21K 9/69; F21K 9/237; F21V 5/04

(52) U.S. Cl. CPC F21K 9/69; F21K 9/237; F21V 5/048

(57) ABSTRACT

A light emitting device includes a semiconductor light source device including a plurality of semiconductor light emitting elements, a wavelength conversion member that converts a wavelength of irradiation light from the semiconductor light source device, a concentrating lens that disposed between the semiconductor light source device and the wavelength conversion member and concentrates the irradiation light from the semiconductor light source device, and a cylindrical holder. The semiconductor light source device, the wavelength conversion member and the concentrating lens is supported by a support portion provided in an inner diameter portion of the cylindrical holder.

### BACKGROUND

### 1. Field

The present disclosure relates to a light emitting device including a semiconductor light source.

### 2. Description of the Related Art

In general, a light emitting device including a semiconductor light emitting element, a wavelength conversion unit disposed in irradiation direction of the semiconductor light emitting element, and a concentrating lens that is disposed between the semiconductor light emitting element and the wavelength conversion unit, and concentrates irradiation light from the semiconductor light emitting element is known (for example, refer to Japanese Unexamined Patent Application Publication No. 2016-9693 (published on Jan. 18, 2016)). In the light emitting device, the wavelength conversion unit contains a phosphor that emits light after being excited by the irradiation light from the semiconductor light emitting element through the concentrating lens. The light emitting device is configured to emit a desired emission color by appropriately selecting a wavelength of the irradiation light of the semiconductor light emitting element, and the number and type of phosphors contained or laminated in the wavelength conversion unit.

By the way, in a light emitting device having the above configuration, in a case where a concentrating lens falls in the light emitting device, there is a risk that laser light irradiated from a semiconductor light emitting element is directly emitted out of a light emitting device. In addition, in the light emitting device that combines the semiconductor light emitting element and the wavelength conversion member, a so-called yellow ring phenomenon may occur, in which a color differs between a central portion and an outer circumferential portion of an irradiation surface.

Additionally, it is difficult to obtain an emission color in a wavelength range of green to orange, in a range of 530 to 630 nm, with a single semiconductor light emitting element. A combination of a plurality of light emitting elements is a method for obtaining a desired emission color by the semiconductor light emitting element. For example, in order to obtain a yellow light emission, a combination of two of a green semiconductor light emitting element and a red semiconductor light emitting element to emit light at an appropriate intensity ratio is the method. Alternatively, a desired emission color can be freely obtained by combining three of a blue semiconductor light emitting element, a green semiconductor light emitting element, and a red semiconductor light emitting element, and appropriately changing each light emission intensity.

However, in a case where there is no need to change the emission color, it is favorable in cost to combine the plurality of light emitting elements. Accordingly, it is another method for obtaining a desired emission color, and there is a merit in combining the light emitting semiconductor element and the wavelength conversion member as described in Japanese Unexamined Patent Application Publication No. 2016-9693 (published on Jan. 18, 2016).

An embodiment of the present disclosure has been made in view of the above-described circumstances. It is desirable to provide a light emitting device that has a simple configuration, a high safety in which laser light irradiated from the semiconductor light emitting element is not emitted directly out of the light emitting device, and emits a desired emission color by mixing the laser light and a light from a phosphor which converts the laser light.

### SUMMARY

An embodiment of the present disclosure provides a light emitting device including a semiconductor light source device including a plurality of semiconductor light emitting elements, a wavelength conversion member that includes one or a plurality of phosphors and converts a wavelength of irradiation light from the semiconductor light source device, a concentrating lens that is disposed between the semiconductor light source device and the wavelength conversion member, and concentrates the irradiation light from the semiconductor light source device; and a cylindrical holder, in which the semiconductor light source device, the wavelength conversion member, and the concentrating lens are supported by a support portion provided in an inner diameter portion of the cylindrical holder.

### BRIEF DESCRIPTION OF THE DRAWINGS

FIG. 1 is a cross-sectional diagram of a configuration of a light emitting device according to a first embodiment of the present disclosure.

FIG. 2 is a flowchart of a manufacturing procedure of a light emitting device according to a first embodiment.

FIG. 3A is a schematic diagram of a configuration of a semiconductor light source device according to a first embodiment, and FIG. 3B is a schematic diagram of a configuration of a semiconductor light source device according to a second embodiment.

FIG. 4 is a cross-sectional diagram of an example of a wavelength conversion member according to a first embodiment.

FIG. 5 is a cross-sectional diagram of an example of a wavelength conversion member according to a modification example.

FIGS. 6A and 6B are diagrams of examples of a wavelength conversion member according to a second embodiment, and FIG. 6A is a cross-sectional diagram and FIG. 6B is a top view diagram.

FIG. 7 is a cross-sectional diagram of a configuration of a light emitting device according to a third embodiment of the present disclosure.

FIG. 8 is a flowchart of a manufacturing procedure of a light emitting device according to a third embodiment.

FIG. 9 is a cross-sectional diagram of a configuration of a light emitting device according to a fourth embodiment of the present disclosure.

FIG. 10 is a flowchart of a manufacturing procedure of a light emitting device according to a fourth embodiment.

FIGS. 11A and 11B are diagrams of modification examples of wavelength conversion members.

### DESCRIPTION OF THE EMBODIMENTS

### First Embodiment

Hereinafter, embodiments of the present disclosure will be described in detail.

### Configuration of Light Emitting Device 100

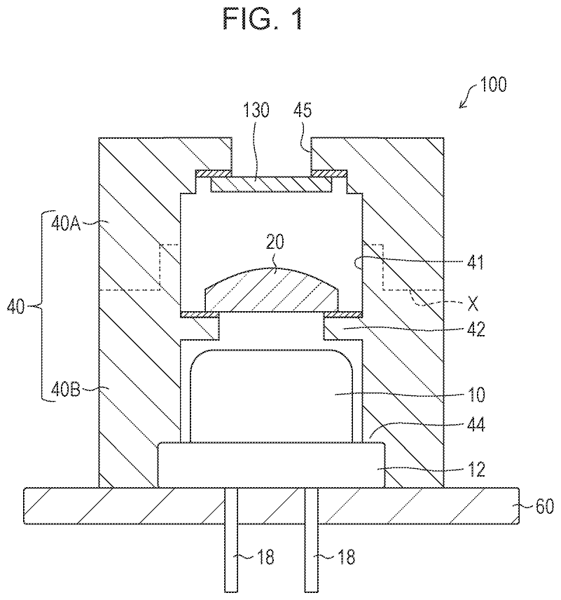

FIG. 1 is a cross-sectional diagram of a configuration of a light emitting device 100 according to a first embodiment of the present disclosure. The light emitting device 100, for example, is a high-output light emitting device that can be used for peak output, such as indoor and outdoor lighting, vehicle-mounted headlamps, and projectors. As shown in FIG. 1, the light emitting device 100 includes a semiconductor light source device 10, a concentrating lens 20, and a wavelength conversion member 130 (phosphor plate). The semiconductor light source device 10, the concentrating lens 20, and the wavelength conversion member 130 are disposed on an inner diameter portion 41 of a cylindrical holder 40.

The semiconductor light source device 10 is a so-called TO-CAN package type light source device using a semiconductor light emitting element, in particular, a semiconductor laser (laser diode: LD) as a light source.

The concentrating lens 20 is an optical member that concentrates irradiation light from the semiconductor light source device 10. As the concentrating lens 20, a biconvex lens can be suitably used. Alternatively, the concentrating lens 20 is, for example, a spherical lens or an aspherical lens, is provided between the semiconductor light source device 10 and the wavelength conversion member 130, and makes an emission light from the semiconductor light source device 10 substantially parallel. A shape (curvature) and material (refractive index, reflectivity and transmissivity) of the lens are not particularly limited, and may be appropriately determined according to a wavelength of the emission light from the semiconductor light source device 10 and the like. The concentrating lens 20 is disposed between the semiconductor light source device 10 and the wavelength conversion member 130.

The wavelength conversion member 130 converts a wavelength of the irradiation light from the semiconductor light source device 10. The wavelength conversion member 130 is desirably provided at a focal position of the concentrating lens 20 where light through the concentrating lens 20 is concentrated. The wavelength of the irradiation light from the semiconductor light source device 10 concentrated in the wavelength conversion member 130 through the concentrating lens 20 is converted through the wavelength conversion member 130 and travels toward an emission opening 45 of the holder 40.

### Configuration of Holder 40

The holder 40 is formed of a material having a high thermal conductivity. A material that is lightweight, has the high thermal conductivity, and is easy to process, such as aluminum, can be suitably used for the holder 40. In addition, the holder 40 is not limited to aluminum, and may be formed of a metal or non-metal material having a thermal conductivity of 10 W/mK or more, more preferably 80 W/mK or more.

Support portions 42, 43, and 44 are provided on the inner diameter portion 41 of the holder 40 at installation positions of the semiconductor light source device 10, the concentrating lens 20, and the wavelength conversion member 130. The support portions 42, 43, and 44 project from the inner diameter portion 41 of the holder 40 and are provided on the inner diameter portion 41 in a step shape. The support portions 42, 43, and 44 may project in a ring shape along a circumferential direction of the inner diameter portion 41, or may partially project.

The support portion 42 is a step that supports the concentrating lens 20 and is referred to as a lens support portion 42. The concentrating lens 20 is bonded to the lens support portion 42 using an adhesive. The concentrating lens 20 is secured to a step surface of the lens support portion 42 on the side facing the emission opening 45 in the holder 40. Although the illustration is omitted, the lens support portion 42 is configured with a pair of steps that projects from the inner diameter portion 41 and faces each other, and the concentrating lens 20 may have a configuration that is supported on the inner diameter portion 41 by pinching the concentrating lens 20 between the pair of steps.

In addition, the emission opening 45 of the holder 40 is closed by wavelength conversion member 130. A wavelength conversion member support portion 43 having a step shape protruding along a circumferential direction inside the inner diameter portion 41 is provided in the emission opening 45 of the holder 40. The wavelength conversion member 130 is bonded and secured to a step surface of the wavelength conversion member support portion 43 using an adhesive to close the emission opening 45. Alternatively, the holder and the wavelength conversion member can be fixed to each other using a metal bump such as a gold bump or an Sn—Au—Cu solder material after metalizing an outer circumferential portion of the wavelength conversion member by metal vapor deposition or the like. Moreover, since a low melting point glass is melted by disposing a ring-shaped low melting point glass between the holder and the wavelength conversion member and treating it in an appropriate temperature range between 300 and 1000 degrees, it is also possible to fix the holder and the wavelength conversion member via the low melting point glass.

In addition, since the light emitted from the outer circumferential portion of the wavelength conversion member 130 is shielded by the emission opening 45 in this way, the phenomenon that the color differs between the central portion and the outer circumferential portion of the irradiation surface, that is, the so-called yellow ring phenomenon is reduced, and an effect of improving color uniformity of the irradiation surface is also obtained.

Further, by the above structure, even when the concentrating lens 20 falls off from the lens support portion 42, the wavelength conversion member 130 remains in luminous flux of the irradiation light from the semiconductor light source device 10. Therefore, since laser light from the semiconductor light source device 10 is not directly emitted from the emission opening 45 without passing through the wavelength conversion member 130, safety can be improved.

Also, although the illustration is omitted, the wavelength conversion member support portion 43 is configured with a pair of steps that projects from the inner diameter portion 41 and faces each other, and may have a configuration that supports the wavelength conversion member 130 on the inner diameter portion 41 by pinching the wavelength conversion member 130 between the pair of steps.

A support portion 44 is a step that supports the semiconductor light source device 10 and is referred to as a light source support portion 44. The semiconductor light source device 10 is pinched and supported between the light source support portion 44 and a heat radiating plate 60 that closes the opening on the light source device side of the holder 40.

The heat radiating plate 60 (plate) is a plate-shaped member formed from a material having a high thermal conductivity. For the heat radiating plate 60, for example, aluminum that is lightweight and has a high thermal conductivity can be suitably used. In addition, the heat radiating plate 60 is not limited to aluminum, and may be formed of a metal or non-metal material having a thermal conductivity of 10 W/mK or more, more preferably 80 W/mK or more.

The semiconductor light source device 10 is mounted via a stem 12 on the heat radiating plate 60 formed of a material having a high thermal conductivity. The heat radiating plate 60 functions as a heat sink for the semiconductor light source device 10 and absorbs heat from the semiconductor light source device 10. Moreover, the heat radiating plate 60 is in contact with the holder 40 and the stem 12 formed of a material having a high thermal conductivity. In this way, the semiconductor light source device 10 is mounted via the stem 12 on the heat radiating plate 60 formed of the material having the high thermal conductivity, and the heat radiating plate 60 is brought into contact with the holder 40 formed of the material having the high thermal conductivity. Accordingly, the heat from the semiconductor light source device 10 can be efficiently radiated from the heat radiating plate 60 and the holder 40. Accordingly, even in a case where output of the semiconductor light source device 10 is increased, heat can be radiated efficiently, and performance and life of the semiconductor light source device 10 can be kept from being affected by heat. A heat radiating structure such as a fin may be appropriately provided on the outer periphery of the holder 40.

### Procedure for Manufacturing Light Emitting Device 100

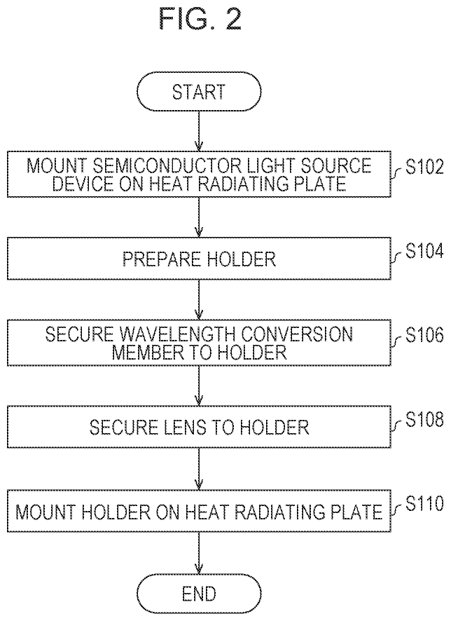

FIG. 2 is a flowchart of a manufacturing procedure of a light emitting device 100. The procedure for assembling the light emitting device 100 can be, for example, as follows.

First, in step S102, the semiconductor light source device 10 is mounted on the heat radiating plate 60. The stem 12 of the semiconductor light source device 10 and the heat radiating plate 60 may be welded or fused. Next, in step S104, the holder 40 including the support portions 42, 43, and 44 is prepared. Next, in step S106, the wavelength conversion member 130 is secured to the wavelength conversion member support portion 43 of the holder 40. Subsequently, in step S108, the concentrating lens 20 is secured to the lens support portion 42 of the holder 40. Next, in step S110, the holder 40 is mounted and secured on the heat radiating plate 60 on which the semiconductor light source device 10 is mounted.

Therefore, the light emitting device 100 includes the support portions 42, 43, and 44 on the inner diameter portion 41 of the holder 40, and the concentrating lens 20, the wavelength conversion member 130, and the semiconductor light source device 10 are supported and secured to the support portions 42, 43, and 44, respectively. Thereby, at the time of assembling the light emitting device 100, the optical axis alignment of the concentrating lens 20, the wavelength conversion member 130, and the semiconductor light source device 10 can be easily performed, and the manufacturing work can be performed efficiently.

In the light emitting device 100 illustrated in FIG. 1, for example, a focal distance of the concentrating lens 20 is f=4.8 mm. The concentrating lens 20 and the wavelength conversion member 130 are arranged such that an interval between them is the focal distance of the concentrating lens 20. Further, the concentrating lens 20 and the semiconductor light source device 10 are arranged such that a distance from a light emitting point of the light source to a major plane of the concentrating lens 20 is 5.8 mm.

The holder 40 is desirably configured as an integral type, and but may have a configuration that is divided in consideration of assembly workability.

For example, as shown in FIG. 1, the holder 40 may be divided into an upper holder 40A and a lower holder 40B in a random position between the wavelength conversion member support portion 43 and the lens support portion 42 as a dividing position X. In this way, the holder 40 is configured to be divided into the upper holder 40A and the lower holder 40B between the wavelength conversion member support portion 43 and the lens support portion 42. Thereby, workability of a work of respectively securing the wavelength conversion member 130 and the concentrating lens 20 to the wavelength conversion member support portion 43 and the lens support portion 42 can be improved.

Furthermore, by appropriately designing a relationship between a size of the wavelength conversion member 130 and a size of the emission opening 45, even in a case where the wavelength conversion member 130 is not secured to the holder 40, the wavelength conversion member 130 remains in the holder 40. In other words, a highly safe light emitting device in which laser light irradiated from a semiconductor laser chip 11 is not directly emitted to the outside of the light emitting device can be provided. For example, in a case where each of the emission opening 45 and the wavelength conversion member 130 is circular, if a diameter of the wavelength conversion member 130 is longer than a diameter of the emission opening, even though the wavelength conversion member 130 is not secured to the holder 40, the wavelength conversion member 130 remains in the holder. Alternatively, in a case where the emission opening 45 is circular and the wavelength conversion member 130 is polygonal, the shortest length of a side length or diagonal length of the wavelength conversion member 130 may be longer than a diameter of the emission opening 45. In a case where both the emission opening 45 and the wavelength conversion member 130 are polygonal, the length of each side is compared with the length of the shortest side of the diagonal length, and the length of the shortest side of the wavelength conversion member 130 may be longer than the diameter of the emission opening 45. As a specific example, the emission opening 45 may be a circle having a diameter of 2.0 mm, and the wavelength conversion member 130 may be a circle having a diameter of 2.5 mm or a square having a side of 2.5 mm. Of course, an absolute value of sizes is not limited to the examples, and by appropriately designing the relationship between the size of the emission opening 45 and the size of the wavelength conversion member 130, in any case, the highly safe light emitting device in which the wavelength conversion member 130 remains inside the holder can be provided. Although only the size relationship between the emission opening 45 and the wavelength conversion member 130 is described above, the same applies to the emission opening 45 and the lens 20. In a case where the lens 20 is not secured to the holder, the size relationship can be designed so that the lens 20 remains in the holder. In other words, the highly safe light emitting device in which laser light irradiated from the semiconductor laser chip 11 is not directly emitted to the outside of the light emitting device can be provided.

### Configuration of Semiconductor Light Source Device 10

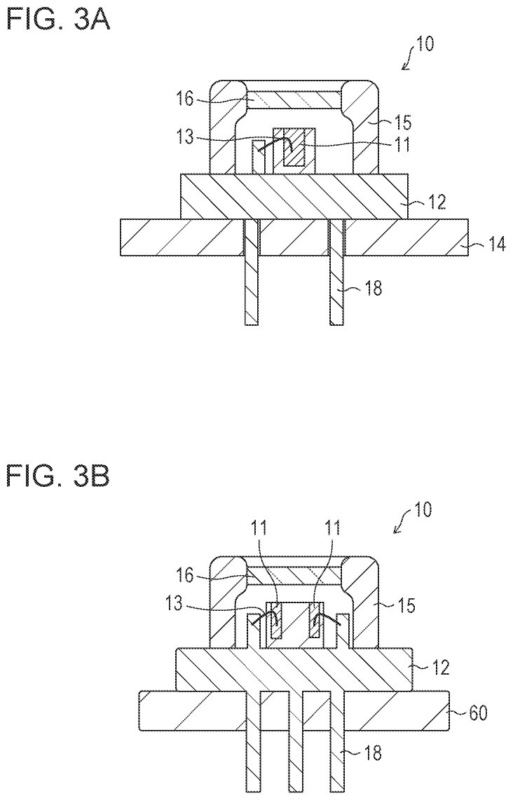

FIGS. 3A and 3B are the diagrams of the configurations of the semiconductor light source device 10. As shown in FIG. 3A, the semiconductor light source device 10 includes one semiconductor laser chip 11 (semiconductor light emitting element), or as shown in FIG. 3B, the semiconductor light source device 10 includes a plurality of semiconductor laser chips 11 (semiconductor light emitting elements). The semiconductor laser chip 11 is a semiconductor laser chip that irradiates ultraviolet light or blue light having an emission peak wavelength in a range of 360 nm to 480 nm. The semiconductor light source device 10 is a TO-CAN package type laser light source device including at least one of the semiconductor laser chips 11. The semiconductor laser chip 11 of the first embodiment is a blue semiconductor laser chip that irradiates blue light, and the semiconductor laser chip 11 is referred to as a blue semiconductor laser chip 11.

The semiconductor light source device 10 includes a stem 12 mounted on the heat radiating plate 60 that is a semiconductor light source substrate, and the blue semiconductor laser chip 11 is coupled to each of a plurality of wires 13 (leads) extending from the stem 12.

The semiconductor light source device 10 includes a can 15 that covers a periphery of the blue semiconductor laser chip 11 and has a metal cap shape. A light-transmitting plate 16 (cover glass) that transmits the irradiation light from the blue semiconductor laser chip 11 is provided in an irradiation opening of the can 15. In addition, a pin 18 extending from the stem 12 extends through the heat radiating plate 60. The blue semiconductor laser chip 11 emits light in a case where power supplied from the pin 18 to the wire 13 is applied.

In a case where a plurality of blue semiconductor laser chips 11 are mounted, each of the semiconductor light source devices 10 is configured to be individually drivable, and a light output can be controlled for each semiconductor laser chip. Therefore, since the semiconductor light source device 10 includes the plurality of semiconductor laser chips 11, the light emitting device 100 can obtain a high-output. Moreover, the semiconductor light source device 10 can individually change each of the light outputs of the plurality of blue semiconductor laser chips 11 stepwise or continuously by changing a size of power supplied to the blue semiconductor laser chip 11 via the wire 13 for each blue semiconductor laser chip 11.

Since the stem 12 is mounted on the heat radiating plate 60, the semiconductor light source device 10 transfers heat from the blue semiconductor laser chip 11 to the heat radiating plate 60, via the heat radiating plate 60 (refer to FIG. 1). A hole through which the pin 18 extending from the stem 12 passes is formed in the heat radiating plate 60, and an external power is coupled to the pin 18 exposed via the hole.

### Procedure for Manufacturing Semiconductor Light Source Device 10

The procedure for assembling the semiconductor light source device 10 can be, for example, as follows.

First, the stem 12 provided with a plurality of pins 18 is prepared. Next, each of the plurality of blue semiconductor laser chips 11 is secured to the stem 12 by die bonding. Subsequently, the wires 13 extending from anode and cathode pins 18 are coupled to each blue semiconductor laser chip 11 by wire bonding. Next, the can 15 is attached so as to cover the periphery of the blue semiconductor laser chip 11 and the wire 13.

### Configuration of Wavelength Conversion Member 130

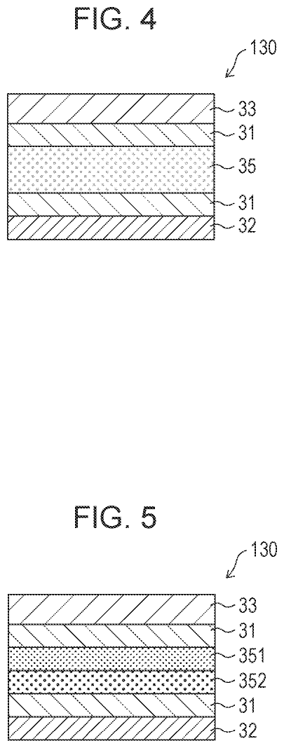

FIGS. 4 and 5 are diagrams illustrating a configuration example of the wavelength conversion member 130, FIG. 4 is a cross-sectional view of an example of the wavelength conversion member 130, and FIG. 5 is a cross-sectional view of another example of the wavelength conversion member 130.

As shown in FIG. 4, the wavelength conversion member 130 has a plurality of layers laminated in a cross-sectional view. In the first embodiment, the wavelength conversion member 130 is formed with a thickness of 0.2 mm, for example. The wavelength conversion member 130 is configured to be laminated with a glass layer 31, a wavelength selective layer 32, a phosphor layer 35, and an antireflection layer 33 formed from sapphire glass as a substrate, for example. Here, the wavelength conversion member 130 may include at least one of a yellow phosphor, a green phosphor, and a red phosphor. Each phosphor layer 35 may be a single layer or a laminated structure.

The wavelength conversion member 130 is a blue phosphor, a green phosphor, a yellow phosphor, or a red phosphor, and includes the phosphor layer 35 having at least one phosphor selected from Ce-activated Ln₃(Al₁₋ₓGaₓ)₅O₁₂ (Ln is selected from at least one of Y, La, Gd, and Lu, and Ce substitutes for Ln), Eu, Ce-activated Ca₃(ScₓMg₁₋ₓ)₂Si₃O₁₂ (Ce substitutes for Ca), Eu-activated (Sr₁₋ₓCaₓ)AlSiN₃ (Eu substitutes for Sr and Ca), Ce-activated (La₁₋ₓYₓ)₃Si₆N₁₁ (Ce substitutes for La and Y), Ce-activated Ca-α-Sialon, Eu-activated β-Sialon, and Eu-activated M₂Si₅N₈ (M is selected from at least one of Ca, Sr, and Ba, and Eu substitutes for M).

The phosphor layer 35 is configured to include one or more types of phosphors, and for example, it may be configured with the yellow phosphor layer 35A. In addition, the phosphor layer 35 is pinched between the glass layers 31.

The phosphor layer 35 may have a multilayer structure made of a phosphor layer 351 having a small particle diameter and a phosphor layer 352 having a large particle diameter, as shown in FIG. 5.

An antireflection layer 33 laminated on the glass layer 31 is formed on a light emission surface of the wavelength conversion member 130. The antireflection layer 33 blocks reflection of excitation light excited in the phosphor layer 35.

The wavelength selective layer 32 laminated on the glass layer 31 is formed on a light incident surface of the wavelength conversion member 130. The wavelength selective layer 32 is configured by a dichroic mirror and transmits only light in a blue wavelength range.

In this way, the wavelength conversion member 130 can emit only the light in the blue wavelength range, which is the irradiation light from the semiconductor light source device 10 and selected by the wavelength selective layer 32, by being excited in the phosphor layer 35. In a case where the phosphor layer 35 includes a yellow phosphor layer 35 and a red phosphor layer, the phosphor layer 35 is excited by a laser light having the emission peak wavelength in a range of 360 nm to 480 nm, and emits a white light with high color rendering properties.

### Second Embodiment

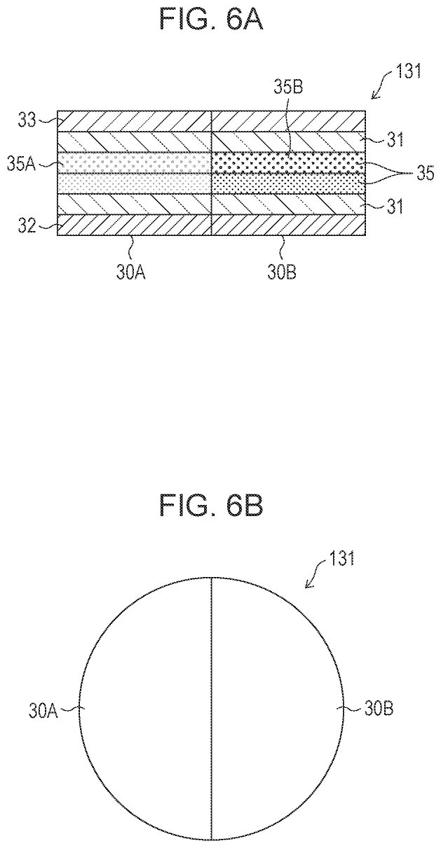

FIGS. 6A and 6B are cross-sectional diagrams of configurations of a wavelength conversion member 131 according to the second embodiment. Here, differences between a light emitting device 101 according to the second embodiment of the present disclosure and the light emitting device 100 according to the first embodiment of the present disclosure will be described below. For the sake of convenience of explanation, members having the same function as members described in the first embodiment are given the same reference sign, and thus description thereof will not be repeated.

### Configuration of Light Emitting Device 101

The light emitting device 101 according to the second embodiment is different from the light emitting device 100 according to the first embodiment in that the semiconductor light source device 10 has a plurality of semiconductor laser chips as shown in FIG. 3B, and the wavelength conversion member is a wavelength conversion member 131 having a plurality of regions as shown in FIGS. 6A and 6B. As will be described below, at least one of the semiconductor laser chips is irradiated on one region of the wavelength conversion member, and the other semiconductor laser chip is irradiated on the other region of the wavelength conversion member. That is, an emission spectrum can be emitted from the light emitting device 101 by configurations of each region of the wavelength conversion member and methods of driving each semiconductor laser chips mounted on the semiconductor light source device 10. In addition, in the light emitting device of the present embodiment, similarly to the light emitting device 100, even in a case where the concentrating lens 20 falls off, the wavelength conversion member 131 remains in luminous flux of the irradiation light from the semiconductor light source device 10. Therefore, the laser light is not directly emitted to the outside, and safety can be improved.

As shown in FIGS. 6A and 6B, the wavelength conversion member 131 may be divided into a plurality of regions as seen from an emission direction. In the examples shown in FIGS. 6A and 6B, the wavelength conversion member 130 is divided into two parts, a first region 30A and a second region 30B, at a position passing through a center. The first region 30A includes the phosphor layer 35 made of the yellow phosphor layer 35A having a phosphor multi-layer film structure including a film containing a yellow phosphor having a small particle diameter and a film containing a yellow phosphor having a large particle diameter. In addition, the second region 30B includes the phosphor layer 35 made of the red phosphor layer 35B having a phosphor multi-layer film structure including a film containing a red phosphor having a small particle diameter and a film containing a red phosphor having a large particle diameter.

The first region 30A and the second region 30B include the glass layer 31 respectively pinching the yellow phosphor layer 35A and the red phosphor layer 35B, the antireflection layer 33 provided on the light emission surface by being laminated on the glass layer 31, and the wavelength selective layer 32 provided on the light incident surface by being laminated on the glass layer 31.

Each region of the wavelength conversion member 131 has a configuration in which irradiation light from at least one of the plurality of blue semiconductor laser chips 11 is incident. The light emitting device 101 appropriately selects a configuration of the wavelength conversion member by individually driving each light output of the plurality of blue semiconductor laser chips 11 included in the semiconductor light source device 10. Thereby, a light emission of light excited by each region of the wavelength conversion member 131 can be changed, and an emission color can be continuously changed not only white but also reddish light to bluish light. For example, the light source device 10 includes two blue semiconductor laser chips 11, and in a case where the first region 30A of the wavelength conversion member 131 includes a Ce-activated Ln₃(Al₁₋ₓGaₓ)₅O₁₂ (Ln is selected from at least one of Y, La, Gd, and Lu, and Ce substitutes for Ln) as a phosphor and the second region 30B includes Ce-activated Ca-α-Sialon as a phosphor, white daylight can be emitted from the first region 30A, and red light can be emitted from the second region 30B. That is, since a light output ratio obtained from the first region and the second region is changed by changing a driving current balance to each of the blue semiconductor laser chips 11, light colors from the white daylight color to light bulb color can be obtained. In this way, since the light emitting device 101 includes the plurality of blue semiconductor laser chips 11 and the wavelength conversion member 131 including a plurality of regions each including one or a plurality of types of phosphors, it is possible to provide the light emitting device having a high-output and variable emission colors with a simple configuration.

Although the configuration example in which the wavelength conversion member 131 is equally divided at the position passing through the center is described above, the configuration of the wavelength conversion member 131 is not limited to this. In the wavelength conversion member 131, the first region 30A and the second region 30B are formed with different diameter dimension, and the second region 30B having a smaller diameter dimension may be faced to the semiconductor light source device 10, and may be laminated mutually with the center positions aligned in the emission direction.

In addition, the wavelength conversion member 131 may be configured such that the first region 30A is provided on an outer periphery of the second region 30B and the first region 30A and the second region 30B divide the diameter of the wavelength conversion member 131.

### Third Embodiment

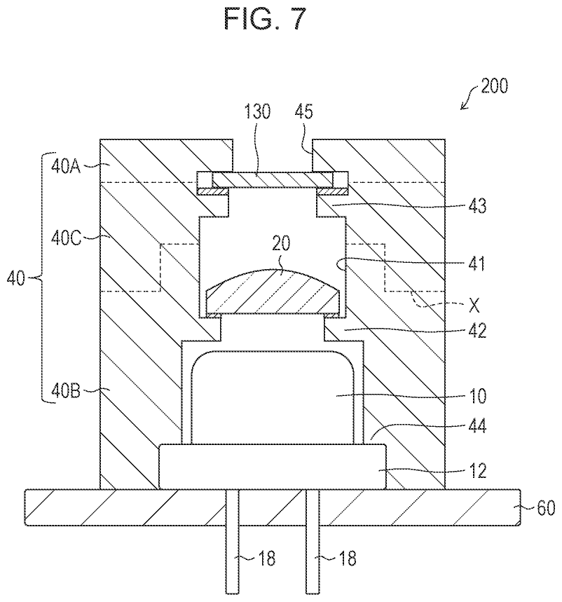

FIG. 7 is a cross-sectional diagram of a configuration of a light emitting device 200 according to a third embodiment. Here, differences between a light emitting device 200 according to the second embodiment of the present disclosure and the light emitting device 100 according to the first embodiment of the present disclosure will be described below. For the sake of convenience of explanation, members having the same function as members described in the first embodiment are given the same reference sign, and thus description thereof will not be repeated.

### Configuration of Light Emitting Device 200

As shown in FIG. 7, the holder 40 of the light emitting device 200 according to the third embodiment is configured with an upper holder 40A, a lower holder 40B, and a middle holder 40C. In addition, the middle holder 40C includes the wavelength conversion member support portion 43 which is a step for supporting the wavelength conversion member 130. The wavelength conversion member 130 is bonded to the wavelength conversion member support portion 43 using an adhesive. The wavelength conversion member 130 is secured to the step surface of the wavelength conversion member support portion 43 on the side opposite to the semiconductor light source device 10 in the holder 40. Thus, even in a case where the concentrating lens 20 falls off, the wavelength conversion member 130 remains in luminous flux of the irradiation light from the semiconductor light source device 10. Therefore, the laser light is not directly emitted to the outside, and safety can be improved.

Here, a manufacturing process of the light emitting device 200 according to the second embodiment will be described below.

### Procedure for Manufacturing Light Emitting Device 200

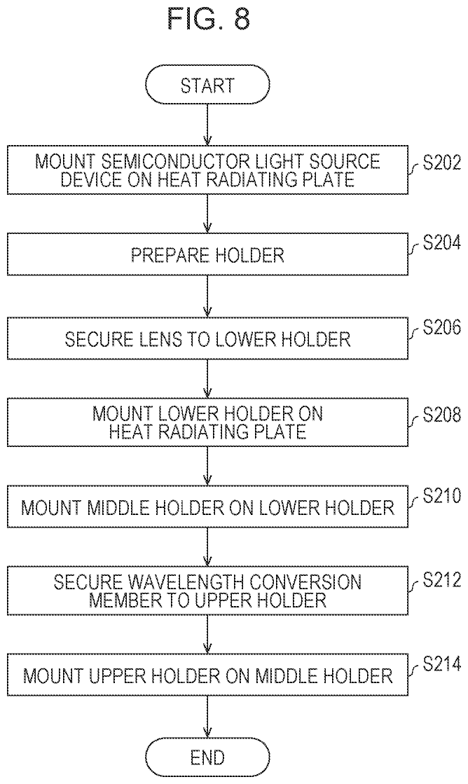

FIG. 8 is a flowchart of a manufacturing procedure of the light emitting device 200 according to the third embodiment. With reference to FIG. 8, the manufacturing procedure of the light emitting device 200 will be described. First, in step S202, the semiconductor light source device 10 is mounted on the heat radiating plate 60. Next, the holder 40 is prepared in step S204. The holder 40 is configured with an upper holder 40A, a lower holder 40B, and a middle holder 40C, as described above. First, in step S206, the concentrating lens 20 is secured to the lower holder 40B. Thereafter, in step S208, the lower holder 40B is mounted on the heat radiating plate 60.

Next, in step S210, the middle holder 40C is mounted on the lower holder 40B. Subsequently, in step S212, the wavelength conversion member 130 is secured to the upper holder 40A. Finally, in step S214, the upper holder 40A is mounted on the middle holder 40C.

With the above procedure, the light emitting device 200 shown in FIG. 7 is completed.

In the above-described process, the holder 40 is divided into the upper holder 40A, the lower holder 40B, and the middle holder 40C by a dividing position X between the lens support portion 42 and the wavelength conversion member support portion 43 and a dividing position Y above the wavelength conversion member support portion 43. The concentrating lens 20 is secured to the lower holder 40B, and the wavelength conversion member 130 is secured to the upper holder 40A, and then, the upper holder 40A, the lower holder 40B, and the middle holder 40C are mounted. Thereby, manufacturing efficiency can be improved.

### Fourth Embodiment

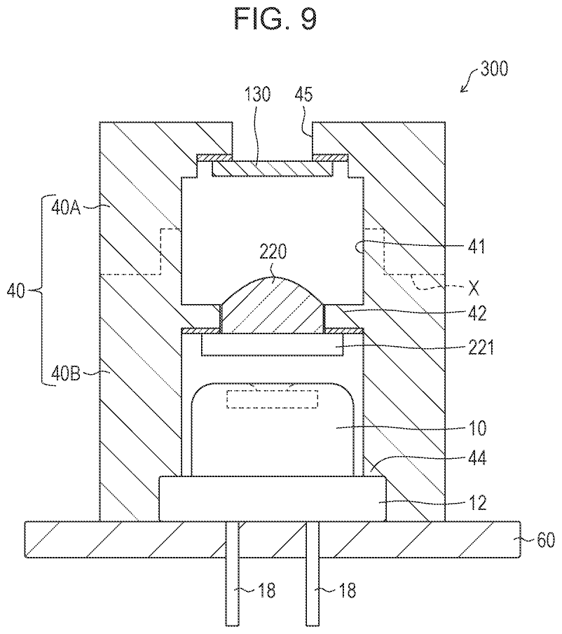

FIG. 9 is a cross-sectional diagram of a configuration of a light emitting device 300 according to a fourth embodiment. Here, differences between a light emitting device 300 according to the fourth embodiment and the light emitting device 100 according to the first embodiment will be described below. For the sake of convenience of explanation, members having the same function as members described in the first embodiment are given the same reference sign, and thus description thereof will not be repeated.

### Configuration of Light Emitting Device 300

In the light emitting device 300 according to the fourth embodiment, although a shape of a concentrating lens 220 is different from the shape of the concentrating lens 20 in the first embodiment, other configurations are the same as the configurations in the first embodiment. The holder 40 of the light emitting device 300 according to the fourth embodiment is configured with the upper holder 40A and the lower holder 40B as in the first embodiment. Further, the lower holder 40B is provided with the lens support portion 42, which is a step that pinches the concentrating lens 220. The lens support portion 42 is a step portion having a ring-shape protruding from the holder inner diameter portion 41. The lens 220 according to the fourth embodiment includes a rim portion 221 at a lower portion, and a diameter of the rim portion 221 is larger than a diameter of the lens support portion 42 provided on the holder 40. Then, the rim portion 221 is bonded to a surface of the lens support portion 42 facing the semiconductor light source device 10 with an adhesive. Alternatively, the holder and the rim portion 221 can be fixed to each other using a metal bump such as a gold bump or an Sn—Au—Cu solder material after metalizing an outer circumferential portion of the rim portion 221 by metal vapor deposition or the like. Moreover, since a low melting point glass is melted by disposing a ring-shaped low melting point glass between the holder and the rim portion 221 and treating it in an appropriate temperature range between 300 and 1000 degrees, it is also possible to fix the holder and the rim portion via the low melting point glass.

Even in the light emitting device 300 having the above-described configuration, even in a case where the concentrating lens 220 falls off, the wavelength conversion member 130 remains in luminous flux of the irradiation light from the semiconductor light source device 10. Therefore, the laser light is not directly emitted to the outside, and safety can be improved.

### Procedure for Manufacturing Light Emitting Device 300

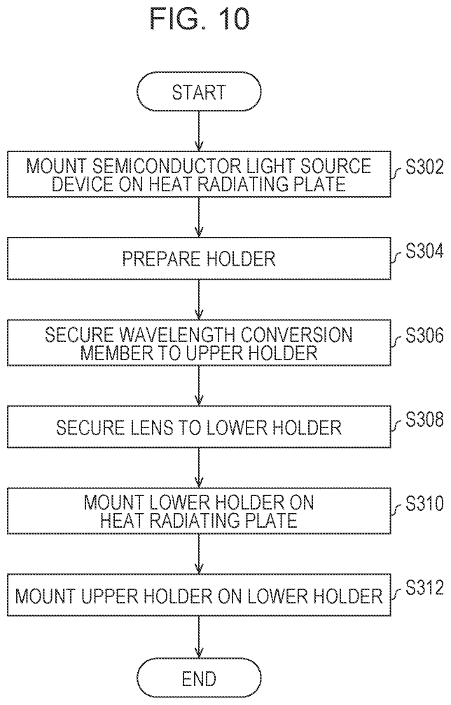

FIG. 10 is a flowchart of a manufacturing procedure of the light emitting device 300 according to the fourth embodiment. Hereinafter, with reference to FIG. 10, a manufacturing process of the light emitting device 300 according to the fourth embodiment will be described.

First, in step S302, the semiconductor light source device 10 is mounted on the heat radiating plate 60. Next, the holder 40 is prepared in step S304. The holder 40 is configured with the upper holder 40A, and the lower holder 40B, as described above. First, in step S306, the wavelength conversion member 130 is secured to the upper holder 40A. Next, in step S308, the concentrating lens 220 is secured to the lower holder 40B. An order of step S306 and step S308 may be reversed. Thereafter, in step S310, the lower holder 40B is mounted on the heat radiating plate 60. Finally, in step S312, the upper holder 40A is mounted on the lower holder 40B.

With the above procedure, the light emitting device 300 shown in FIG. 9 is completed.

Even in the manufacturing procedure described above, the concentrating lens 220 is secured to the lower holder 40B, and the wavelength conversion member 130 is secured to the upper holder 40A, and then, the upper holder 40A is mounted on the lower holder 40B. Thereby, manufacturing efficiency can be improved.

### Modification Example of Configuration of Wavelength Conversion Member 130

The wavelength conversion member used in the first to fourth embodiments is not limited to the structure of the wavelength conversion member 130 described above, and may have the following structure.

The wavelength conversion member may be a plate-shaped member made of only a phosphor, and for example,
a member that single crystal phosphor is cut into a plate-shape,
a member that phosphor particles are sintered into a plate-shape,
a member that phosphor particles and particles having light scattering function are mixed and sintered into a plate-shape,
a member that phosphor particles are compression-molded into a plate-shape,
a member that is compression-formed by mixing the phosphor particles and light scattering particles, and
a member that the phosphor particles are coated and formed in a layer-shape on a substrate transparent formed of sapphire, glass, or the like, using an organic binder or inorganic binder can be used. In addition, the phosphor layer in the wavelength conversion member 130 and the wavelength conversion member having the simple structure described above may have voids depending on the formation method thereof. Therefore, a light scattering is affected, and the light scattering increases as the amount of voids increases. Further, the wavelength conversion member may be the structure of 130 or a combination of a plurality of the above structures.

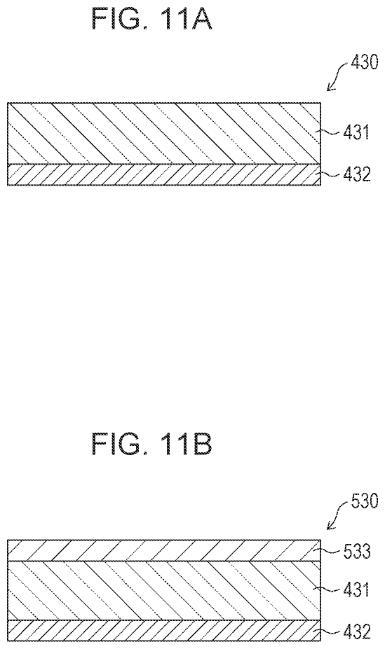

FIGS. 11A and 11B are diagrams of configurations of wavelength conversion members 430 and 530 which are modification examples.

As shown in FIG. 11A, the wavelength conversion member 430 may be formed a wavelength selective light-reflecting region 432 having such a characteristic that reflects a phosphor light, on an incident side of light from a laser of a plate-shaped member 431 made of only the phosphor described above. The light-reflecting region 432 can be configured with the dichroic mirror.

Furthermore, as shown in FIG. 11B, the wavelength conversion member 530 may also form the dichroic mirror or a wavelength selective light-absorbing color filter layer 533, which have characteristics that reflect light from a laser of either the plate-shaped member (phosphor plate) 431 made of only the phosphor or a member (431+432) in which the light-reflecting region 432 is formed on the plate-shaped member 431 made of only the phosphor, on the light emission side from the laser. A design of reflectivity of the dichroic mirror or transmitting spectral characteristic of the color filter is appropriately changed in accordance with a desired characteristic of the spectra of the light emitted from the semiconductor light source device.

The wavelength conversion member may be a member that forms have the light scattering layer on the incident side of the light from the laser, or on both the incident side and the emission side of the light from the laser of the plate-shaped member made of only the phosphor.

In addition, in order to suppress in-plane guided in the plate-shaped member made of only the phosphor, the wavelength conversion member may have a configuration which includes a reflection film or a reflective layer formed by a metal film or a dichroic mirror on both sides of the phosphor plate. In this way, light extraction efficiency from the emission surface of the wavelength conversion member can be improved by providing the reflection film or the reflective layer on both sides of the phosphor plate.

The present disclosure contains subject matter related to that disclosed in U.S. Provisional Patent Application No. 62/808,556 filed in the US Patent Office on Feb. 21, 2019, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A light emitting device comprising:
a semiconductor light source device including one or a plurality of semiconductor light emitting elements;
a wavelength conversion member that includes one or a plurality of phosphors and converts a wavelength of irradiation light from the semiconductor light source device;
a concentrating lens that is disposed between the semiconductor light source device and the wavelength conversion member, and concentrates the irradiation light from the semiconductor light source device; and
a cylindrical holder having an emission opening and a plurality of support portions provided in an inner diameter portion of the cylindrical holder,
wherein the concentrating lens is supported by a concentrating lens support portion being one of the support portions.

2. The light emitting device according to claim 1,
wherein the wavelength conversion member is attached on a side of the concentration lens of the emission opening of the cylindrical holder.

3. The light emitting device according to claim 1,
wherein the cylindrical holder includes an upper holder and a lower holder, and the lower holder includes the concentrating lens support portion.

4. The light emitting device according to claim 1,
wherein the concentrating lens and the emission opening are each circular, and a diameter of the concentrating lens is longer than a diameter of the emission opening.

5. The light emitting device according to claim 1,
wherein the wavelength conversion member and the emission opening are each circular, and a diameter of the wavelength conversion member is longer than a diameter of the emission opening.

6. The light emitting device according to claim 1,
wherein the emission opening is circular, the wavelength conversion member is polygonal, and a shortest length of a side length or a diagonal length of the wavelength conversion member is longer than a diameter of the emission opening.

7. The light emitting device according to claim 3,
wherein the cylindrical holder further includes a middle holder disposed between the upper holder and the lower holder.

8. The light emitting device according to claim 1,
wherein at least one of an adhesive, a metal bump, a solder, and a low melting point glass is disposed on a surface of the support portions.

9. The light emitting device according to claim 1,
wherein the concentrating lens support portion is configured with a pair of steps that projects from the inner diameter portion and faces each other.

10. The light emitting device according to claim 1,
wherein the concentrating lens further includes a rim portion on a surface of the concentrating lens on a side of the semiconductor light source device.

11. The light emitting device according to claim 1,
wherein the semiconductor light source device is mounted on a plate formed from a member having a high thermal conductivity.

12. The light emitting device according to claim 1,
wherein the semiconductor light emitting element mounted on the semiconductor light source device is at least one ultraviolet or blue semiconductor laser element having an emission peak wavelength in a range of 360 nm to 480 nm.

13. The light emitting device according to claim 1,
wherein the wavelength conversion member is a blue phosphor, a green phosphor, a yellow phosphor, or a red phosphor, and includes at least one selected from Ce-activated Ln₃ (Al₁₋ₓGaₓ)₅O₁₂ (Ln is selected from at least one of Y, La, Gd, and Lu, and Ce substitutes for Ln), Eu, Ce-activated Ca₃(ScₓMg₁₋ₓ)₂Si₃O₁₂ (Ce substitutes for Ca), Eu-activated (Sr₁₋ₓCaₓ)AlSiN₃ (Eu substitutes for Sr and Ca), Ce-activated (La₁₋ₓYₓ)₃Si₆N₁₁ (Ce substitutes for La and Y), Ce-activated Ca-α-Sialon, Eu-activated β-Sialon, and Eu-activated M₂Si₅N₈ (M is selected from at least one of Ca, Sr, and Ba, and Eu substitutes for M).

14. The light emitting device according to claim 1,
wherein the wavelength conversion member is divided into a plurality of regions as seen from an emission direction.

15. A light emitting device comprising:
a semiconductor light source device including one or a plurality of semiconductor light emitting elements;
a wavelength conversion member that includes one or a plurality of phosphors and converts a wavelength of irradiation light from the semiconductor light source device;
a concentrating lens that is disposed between the semiconductor light source device and the wavelength conversion member, and concentrates the irradiation light from the semiconductor light source device; and
a cylindrical holder having an emission opening and a plurality of support portions provided in an inner diameter portion of the cylindrical holder,
wherein the wavelength conversion member is supported by a wavelength conversion member support portion being one of the support portions and is attached on an underside of the emission opening where the concentrating lens is disposed.
